(19) United States
(12) Patent Application Publication
(10) Pub. No.: US 2005/0181633 A1
(43) Pub. Date: Aug. 18, 2005

(54) Precursors for depositing silicon-containing films and processes thereof

(76) Inventors: Arthur Kenneth Hochberg, Solana Beach, CA (US); Kirk Scott Cuthill, Vista, CA (US); Thomas Alan Deis, Pittsburgh, PA (US); Lisa A. Deis, Pittsburgh, PA (US); Andre Lagendijk, Oceanside, CA (US)

Correspondence Address: AIR PRODUCTS AND CHEMICALS, INC.;PATENT DEPARTMENT, 7201 HAMILTON BOULEVARD, ALLENTOWN, PA, 181951501, US

(21) Appl. No.: 10/780,183

(22) Filed: Feb. 17, 2004

(51) Int. Cl. C23C 16/48; H01L 21/31; H01L 21/469

(52) U.S. Cl. 438/787; 438/791

(57) ABSTRACT

Inorganic precursors, namely iodosilane precursors, for the low temperature, low pressure deposition of silicon-containing films is provided therein. In one aspect, there is provided a process for forming a silicon-containing film process comprising: introducing a substrate and gaseous reagents comprising an iodosilane precursor having three or less iodine atoms bound to the silicon atom and at least one reagent selected from an oxygen-containing reactive gas, a nitrogen-containing reactive gas, a hydrogen-containing reactive gas and mixtures thereof into a reaction chamber; heating the reaction chamber to one or more temperatures ranging from 200° C. to 900° C. to form the silicon containing film on the substrate, provided that if the iodosilane precursor has three iodine atoms bound to the silicon atom then the heating step is conducted at one or more pressures less than 600 Torr.

### BACKGROUND OF THE INVENTION

In the fabrication of semiconductor devices, one or more thin layers of chemically inert, silicon containing dielectric films such as silicon nitride (Si₃N₄), silicon oxynitride, and silicon oxide may be needed. Silicon-containing dielectric films can be used on semiconductor devices as, for example, diffusion barriers, gate insulators for trench isolation, and capacitor dielectrics. These films may function, for example, as diffusion masks, oxidation barriers, intermetallic dielectric material with high dielectric breakdown voltages and passivation layers. For example, silicon-containing films, such as silicon nitride films, may be used as sidewall spacers in MOS devices and, with oxides, such as silicon oxynitride films, gate dielectrics for Groups IV and II-V transistors. Many other applications of silicon-containing dielectric films in the fabrication of semiconductor devices are reported elsewhere, see, i.e., Semiconductor and Process technology handbook, edited by Gary E. McGuire, Noyes Publication, New Jersey, (1988), pp 289-301; and Silicon Processing for the VLSI ERA, Wolf, Stanley, and Talbert, Richard N., Lattice Press, Sunset Beach, Calif. (1990), pp 20-22, 327-330.

Deposition of silicon- and nitrogen-containing films has been accomplished using many precursors. Several classes of chemicals are used as precursors for silicon nitride film deposition. Among them are silanes, chlorosilanes, polysilazanes, aminosilanes, organosilanes, and azidosilanes. These precursors are not without drawbacks.

Sorita et al., J. Electro. Chem. Soc, Vol. 141, No. 12, (1994), pp. 3505-3511, describe deposition of silicon nitride using dichlorosilane and ammonia using a low pressure chemical vapor deposition (LPCVD) process at temperatures exceeding 750° C. These high deposition temperatures are needed to obtain reasonable growth rates and uniformities as well as optimize film properties. Further, dichlorosilane is a pyrophoric, toxic compressed gas.

B. A. Scott, J. M. Martnez-Duart, D. B. Beach, T. N. Nguyen, R. D. Estes and R. G. Schad, Chemtronics, 1989, Vol. 4, pp. 230-234, report deposition of silicon nitride using silane and ammonia by LPCVD at temperatures ranging from 250 to 400° C. Silane, however, is a pyrophoric gas and is difficult to control for the deposition of clean silicon nitride due to partial gas phase reaction.

J. M. Grow, R. A. Levy, X. Fan and M. Bhaskaran, Materials Letters, 23, (1995), pp. 187-193, describe deposition of silicon nitride using ditertiarybutylsilane and ammonia by a LPCVD process at temperatures ranging from 600 to 700° C. The deposited silicon nitride films were contaminated with carbon impurities (around 10 atomic %). This may be due to the presence of direct Si—C bonds in the precursor.

W-C. Yeh, R. Ishihara, S. Moishita, and M. Matsumura, Japan. J. Appl. Phys., 35, (1996) pp. 1509-1512, describe a low temperature deposition of a silicon-nitrogen film using hexachlorodisilane and hydrazine near 350° C. The films are unstable in air and slowly convert to a silicon-oxygen film.

A. K. Hochberg and D. L. O'Meara, Mat. Res. Soc. Symp. Proc, Vol. 204, (1991), pp 509-514, report deposition of silicon nitride and silicon oxynitride by using diethylsilane with ammonia and nitric oxide using a LPCVD method. The deposition was carried out in temperatures ranging from 650° C. to 700° C. The deposition is limited to deposition at or above 650° C.; at lower deposition temperatures, the deposition rate drops to below 4 Å/min. Further, precursors that contain direct Si—C carbon bonds such as diethylsilane may cause carbon contamination in the films. To avoid this, depositions using carbon-free precursors may be conducted using a 5:1 NH₃ to silicon precursor ratios. However, at lower ammonia concentrations, the films were still found to contain carbon. Diethylsilane and ammonia processes typically require covered boats or temperature ramping to improve uniformities across the wafers.

U.S. Pat. No. 5,874,368 describes depositing a silicon-nitrogen film at temperatures below 550° C. using the organosilane, bis(tertarybutylamino)silane (“BTBAS”). This temperature may still be too high for depositions on circuits with metallization and on many Group III-V and II-VI devices. In addition, the precursor has a high activation energy that makes the process very temperature sensitive. These films contain significant amounts of carbon.

Published patent application U.S. 2002/0119327 describes a method for deposition at about atmospheric pressure of a silicon based film using an iodosilane precursor in the vapor state having at least three iodine atoms bound to silicon.

The trend of miniaturization of semiconductor devices and low thermal budget requires lower process temperatures and higher deposition rate. A process involving a typical organosilicon precursor such as BTBAS requires process temperature of at least 550° C. Chlorosilanes need temperatures even higher. Accordingly, there is a need in the art for precursor for silicon-containing dielectric films that are formed at relatively lower thermal and pressure conditions and have reduced carbon, chloride, or other contamination.

### BRIEF SUMMARY OF THE INVENTION

The present invention satisfies some, if not all, of the needs of the art by providing an inorganic precursor for the chemical vapor deposition of a silicon-containing film and a method, silicon-containing film, and reaction mixture comprising same. In one aspect of the present invention, there is provided a process for forming a silicon-containing film comprising: introducing a substrate and gaseous reagents comprising an iodosilane precursor having three or less iodine atoms bound to the silicon atom and at least one reagent selected from an oxygen-containing reactive gas, a nitrogen-containing reactive gas, a hydrogen-containing reactive gas, a silicon-containing precursor, and mixtures thereof into a reaction chamber; and heating the reaction chamber to one or more temperatures ranging from 200° C. to 900° C. to form the silicon-containing film on the substrate, provided that if the iodosilane precursor has three iodine atoms bound to the silicon atom then the heating step is conducted at one or more pressures less than 600 Torr.

In another aspect of the present invention, there is provided a process for the chemical vapor deposition of a silicon-containing film on a substrate comprising: contacting an iodosilane precursor having three or less iodine atoms bound to the silicon atom with at least one reagent selected from a nitrogen-containing reactive gas, an oxygen-containing reactive gas, a hydrogen-containing reactive gas, a silicon-containing precursor, and mixtures thereof at one or more temperatures ranging from 200° C. to 600° C. and one or more pressures less than 600 Torr to form the silicon-containing film on the substrate.

In a further aspect of the present invention, there is provided a process for low temperature chemical vapor deposition of a silicon-containing film on a substrate comprising: heating the substrate to a temperature ranging from 200° C. to 600° C. and a pressure ranging from 10 milliTorr (mTorr) to 20 Torr in a reaction chamber; introducing gaseous reagents comprising an iodosilane precursor having three or less iodine atoms bound to the silicon atom and an at least one reagent selected from an oxygen-containing reactive gas, a nitrogen-containing reactive gas, a hydrogen-containing reactive gas, a silicon-containing precursor, and mixtures thereof into the reaction chamber; and maintaining the temperature and pressure for a period of time sufficient to deposit the silicon-containing film on the substrate.

In yet another aspect of the present invention, there is provided a process for the deposition of a silicon-containing film on a substrate comprising: reacting an iodosilane precursor having a formula I₍₄₋ₙ₎SiHₙ wherein n=1, 2, or 3 with at least one reagent selected from an oxygen-containing reactive gas, a nitrogen-containing reactive gas, a hydrogen-containing reactive gas, a silicon-containing precursor, and mixtures thereof provided that if n=1 then the reacting step is conducted at a pressure ranging from 10 mTorr to 20 Torr.

In another aspect of the present invention, there is provided a silicon-containing film formed by chemical vapor deposition of an iodosilane having a formula I₍₄₋ₙ₎SiHₙ wherein n=1, 2, or 3 wherein the chemical vapor deposition is conducted at a temperature ranging from 200° C. to 600° C. and a pressure ranging from 10 mTorr to 20 Torr.

In a still further aspect of the present invention, there is provided a reactive mixture for the deposition of a silicon-containing film comprising: an iodosilane having a formula I₍₄₋ₙ₎SiHₙ wherein n=1 or 2 and at least one reagent selected from an oxygen-containing reactive gas, a nitrogen-containing reactive gas, a hydrogen-containing reactive gas, a silicon-containing precursor, and mixtures thereof.

These and other aspects of the invention will become apparent from the following detailed description.

### DETAILED DESCRIPTION OF THE INVENTION

Inorganic precursors, namely iodosilane precursors, for the low temperature, low pressure deposition of silicon-containing films is provided therein. These precursors allow for the deposition of silicon-containing films, particularly silicon nitride, silicon oxynitride, silicon oxide, and silicon hydride films without introducing carbon contaminants into the resultant film. Further, the method disclosed herein overcomes the delivery problems that other iodine-containing precursors, such as iodates, may cause by reducing the formation of undesirable reaction byproducts such as ammonium iodide. The precursors taught herein are typically highly volatile, thermally stable, and less hazardous than other silane precursors that are used for the deposition of silicon-containing films.

As used herein, silicon-containing films are those films or coatings, which have silicon as a major component. These films may be stoichiometric or non-stoichiometric in nature. In one embodiment, the silicon-containing films are silicon nitride films having the chemical formula SiₓN_{y} wherein x is a number ranging from greater than 0 to 3 and y is a number ranging from greater than 0 to 4. Examples of silicon nitride films include SiN or Si₃N₄ films as well as non-stoichiometric variations of silicon nitride films. In another embodiment, the silicon-containing films are silicon oxide films having the formula SiO_{y}, wherein y is greater than 0 and preferably no greater than 2.2, or ranges from about 1.8 to about 2.0. In yet another embodiment, the silicon containing films are silicon oxynitride films of the formula SiNₓO_{y} wherein x and y range from greater than 0 to about 2.0 and the sum of x+y is less than or equal to about 3.0. In still another embodiment of the present invention, the silicon-containing films are silicon hydride films having the formula SiₓH_{y}.

The silicon-containing films are typically deposited onto at least a portion of a substrate. Suitable substrates that may be used include, but are not limited to, semiconductor materials such as gallium arsenide (“GaAs”), boronitride (“BN”) silicon, and compositions containing silicon such as crystalline silicon, polysilicon, amorphous silicon, epitaxial silicon, silicon dioxide (“SiO₂”), silicon carbide (“SiC”), silicon oxycarbide (“SiOC”), silicon nitride (“SiN”), silicon carbonitride (“SiCN”), organosilicate glasses (“OSG”), organofluorosilicate glasses (“OFSG”), fluorosilicate glasses (“FSG”), metal substrates, polymeric substrates, and other appropriate substrates or mixtures thereof. Substrates may further comprise a variety of layers to which the film is applied thereto such as, for example, antireflective coatings, photoresists, organic polymers, porous organic and inorganic materials, metals such as copper and aluminum, and/or diffusion barrier layers.

The silicon-containing films are deposited onto at least a portion of a substrate from at least one iodosilane precursor and at least one reagent gas or mixtures thereof using a variety of different methods. These methods may be used by themselves or in combination. Some examples of processes that may be used to form the film include the following: chemical vapor deposition (“CVD”), metal-organic chemical vapor deposition (“MOCVD”), atomic layer deposition (“ALD”), atomic layer chemical vapor deposition (“ALCVD”), plasma enhanced chemical vapor deposition (“PECVD”), low pressure chemical vapor deposition processes (“LPCVD”), thermal CVD, high density PECVD, photon assisted CVD, plasma-photon assisted CVD, cryogenic CVD, chemical assisted vapor deposition, hot-filament chemical vapor deposition, photo initiated chemical vapor deposition, CVD of a liquid polymer precursor, deposition from supercritical fluids, transport polymerization (“TP”), and similar means. Although the precursor(s) and reagent(s) used herein may be sometimes described as “gaseous” or “gases”, it is understood that the chemical reagents may be delivered directly as a gas to the reactor, delivered as a vaporized liquid, a sublimed solid and/or transported by an inert carrier gas into the reactor.

The silicon-containing films are deposited at low pressures. In certain embodiments, the pressure is below atmospheric pressure, or below 600 Torr, or ranges from 10 milliTorr (mTorr) to 20 Torr, or from 10 mTorr to 2000 mTorr, or from 100 mTorr to 400 mTorr. The pressure that may be used may vary depending upon the deposition method selected. For example, the pressure range for a PECVD process may range from 1 to 20 Torr whereas a LPCVD process may range from 0.1 to 20 Torr or from 0.5 to 600 mTorr. The pressure that may be used may also vary depending upon the reactor. For example, in depositions conducted in a furnace reactor, the pressure may range from 50 mTorr to 2000 mTorr, or from 100 mTorr to 400 mTorr, whereas in depositions conducted in a single wafer reactor, the pressure may be 20 Torr.

The silicon-containing films are deposited using a gaseous iodosilane precursor having three or less iodine atoms bound to the silicon atom. One example of an iodosilane precursor is a compound having the formula I₍₄₋ₙ₎SiHₙ wherein n is the number 1, 2, or 3. In one particular embodiment, the silicon-containing films are deposited using the iodosilane precursor, diiodosilane (SiH₂I₂). In another embodiment, the iodosilane precursor has three iodine atoms bound to the silicon atom such as the compound triodosilane (SiHI₃). In the latter embodiment, the deposition of the silicon-containing film is conducted at one or more pressures less than 600 Torr, or from 10 mTorr to 20 Torr, or from 10 to 1000 mTorr.

The iodosilane precursor(s) may be used by itself or in combination with other reagents such as silicon-containing precursors known in the art. Examples of other silicon-containing precursors include, but are not limited to, silane, disilane, dichlorosilane, trichlorosilane, dibromosilane, silicon tetrachloride, silicon tetrabromide.

In certain embodiments, the iodosilane precursor may be used in conjunction with at least one reagent gas(es) such as, but not limited to, a nitrogen-containing reactive gas, an oxygen-containing reactive gas, a hydrogen reactive gas and mixtures thereof to form silicon-containing films with other major components in addition to silicon, such as nitrogen, oxygen, or hydrogen.

In one embodiment, an iodosilane precursor is used in conjunction with a nitrogen-containing reactive gas, such as, for example, ammonia and/or hydrazine, to form a silicon nitride film. In embodiments wherein ammonia is the nitrogen-containing reactive gas, the ratio of the nitrogen-containing reactive gas to iodosilane and/or other silicon-containing precursor(s) during the deposition is at least 0.2:1 depending upon the silicon nitride film desired. In embodiments wherein a stoichiometric Si₃N₄ film is desired, a molar ratio of least 4 moles of nitrogen atoms to at least 3 moles of silicon atoms should be present in the reaction chamber. However, other non-stoichiometric and/or mixed phased films are contemplated. If less than a stoichiometric amount of nitrogen is present in the deposition chamber, then a silicon-rich film, such as SiNₓ, where x<1, will be deposited. If excess active nitrogen is present in the deposition chamber, then a nitrogen-rich film, such as SiNₓ, where x>1, will be deposited. It is possible to vary the stoichiometric relation between the silicon and nitrogen in the resultant film in several ways. For example, the concentration ratio of Si source to active N source in the CVD reaction, substrate temperature, or both may be varied during the deposition process to control the silicon-to-nitrogen ratio in the resulting film. Alternatively, the ratio may be varied by changing the nature of the nitrogen-containing reactive gas. These techniques can produce single, bilayered or other multilayered films with varying silicon-to-nitrogen ratios. In one embodiment, a film can be deposited which has multiple layers of SiNₓ, with x gradually ranging from below 1 for the first layer, i.e., a silicon-rich layer, to above 1 for the last surface layer, i.e., a nitrogen rich layer.

In an alternative embodiment, an iodosilane precursor is used in conjunction with an oxygen-containing reactive gas, such as O₂, O₃, N₂O, NO₂, to form a silicon oxygen film. In this embodiment, the ratio of the oxygen-containing reactive gas to iodosilane and/or other silicon-containing precursor(s) during the deposition may range from 0.1 to 100, or from 0.5 to 10, or from 1 to 4 depending upon the silicon oxygen film desired. In yet another embodiment, the iodosilane precursor(s) and optional other silicon-containing precursor(s) may be used in conjunction with the oxygen-containing reactive gas and nitrogen-containing reactive gas to form a silicon oxynitride film. In forming the SiO_{y} or SiNₓO_{y} films, the ratio of silicon to oxygen, or silicon to oxygen and silicon to nitrogen, respectively can be varied to form silicon-rich, oxygen-rich or nitrogen-rich films or multiphase films in the same manner as noted above with respect to SiNₓ films.

In one embodiment, at least one iodosilane precursor, with or without a carrier gas depending on the delivery system, and at least one reagent gas are introduced into a deposition chamber. The at least one reagent reacts with the at least one iodosilane precursor under appropriate conditions and forms the silicon-containing film on the substrate. As noted above, the reagent gas(es) and/or iodosilane precursor(s) may by combined with one or more inert carrier gas, such as, for example, helium, argon, krypton, neon, xenon, and nitrogen. These gases may be used for example, to dilute the at least one reagent and precursor(s), transport the at least one reagent and precursor(s), or as a purge gas. As described below, it may be preferable that the at least one reactant gas and the iodosilane precursor be delivered separately to prevent premature reaction before the at least one reagent and at least one iodosilane precursor are both within the chamber. For example, at least one reactant gas may be introduced into the reaction chamber followed by a purge gas prior to the introduction of the at least one iodosilane precursor gas.

As noted above, the at least one reagent gas and/or iodosilane precursor gas may be a single gas or gaseous mixture. The at least one reagent gas and/or iodosilane precursor gas may include one or more inert carrier gas, preferably one or more of the noble gases, such as helium, argon, krypton, neon, and/or xenon. Nitrogen may also be introduced along with the reactant gas or iodosilane precursor as a dilution and/or a purge gas as described below. The at least one reagent gas may also include hydrogen; halogens such as fluorine and/or chlorine; nitrogen-containing species such as ammonia for forming silicon nitrides and/or oxygen-containing species for forming silicon oxides and the like. The inert gas(es) can be varied depending upon the type of film to be formed.

In one embodiment of the invention, the silicon-containing films are deposited through a LPCVD process. In this embodiment, the deposition reactions typically occur at one or more pressures ranging from 20 mTorr to 2 Torr and at one or more temperatures ranging from 200° C. to 900° C. or from 400° C. to 600° C. A typical LPCVD process may occur by introducing a reaction mixture containing one or more chemical reagents, each of which may be diluted with an inert or carrier gas, into the reaction chamber. The reagents are allowed to diffuse to the substrate where they are then adsorbed within the substrate. Chemical reactions then occur on the surface, and the gaseous byproducts of the reaction are desorbed, leaving behind the deposited film. These reactions are initiated by one or more energy sources such as, for example, thermal or photon energy. In certain preferred embodiments, thermal energy is used. LPCVD processes may be conducted in horizontal tube hot wall reactors or vertical flow isothermal reactors either of which may be in fluid communication to a vacuum system.

In one aspect of the present invention, certain measures may be used, alone or in combination, to minimize the formation and condensation of reaction byproducts within the reactor equipment or components, including the substrate contained therein. For example, prior to the flow of chemical reagents into the reactor, the lines and components within the reactor may be heated to a temperature of at least 10° C. higher than the vaporization point of the precursor to prevent the condensation of reaction byproducts within the lines and on the components. In embodiments wherein the iodide precursor diiodosilane is used, the lines and components are heated to a temperature of at least 220° C., which is at least 10° greater than its vaporization point of 210° C., to prevent the condensation of ammonia iodide. Further, the gaseous chemical reagents may be injected within a close proximity to the substrate, or about 5 cm or less, preferably about 1 cm or less, and more preferably about 0.5 cm or less to prevent condensation. After the film is formed, the reactor lines and components may be exhausted to a temperature at least 10° C. higher than the vaporization point of the iodide precursor to prevent the condensation of reaction byproducts.

In embodiments wherein the silicon-containing film is deposited via an atomic layer deposition method, the iodosilane vapors are injected onto the substrate for a time ranging from 0.5 to 5 seconds. The reactor is then purged with an inert gas. This may followed by injection of at least one reagent such as an oxygen-containing reactive gas for a desired silicon oxide film, a nitrogen-containing reactive gas for a desired silicon nitride film, or a hydrogen-containing reactive gas for a silicon-hydrogen film. After injection with the at least one reagent, the reactor is purged with an inert gas and then the cycle is repeated.

The invention will be illustrated in more detail with reference to the following Examples, but it should be understood that the present invention is not deemed to be limited thereto.

### EXAMPLES

Silicon nitride films were formed onto silicon wafer substrates using diiodosilane as a precursor. The diiodosilane was purified by vacuum distillation and packaged within an inert atmosphere. Prior to use, the reagent was degassed through a series of freeze and thaw cycles under vacuum. For the depositions, the temperature of the iodosilane precursor was adjusted to provide a chemical vapor pressure of at least 10 Torr (1.33 kPa).

The films were formed in a horizontal flow isothermal reactor with a vacuum system consisting of a rotary vane pump/roots blower combination and various traps. The reactor pressure was controlled by a capacitance manometer feedback to a throttle valve controller. Reactor loading consisted of eighty 100 mm diameter silicon wafers at 9 mm spacing in standard diffusion boats. The boats were positioned on a sled, so that the wafers centers were slightly above the center of the reaction tube. This produced a uniform conductance around the wafer peripheries by compensating for conductance restrictions caused by the boats and the sled. The temperature uniformity across the wafer load for the data presented was ±1° C. as measured by an internal multi-junction thermocouple. Deposition uniformity down the wafer load was improved by using a temperature ramp.

Prior to the flow of the gaseous reagents into the reactor, the lines and components within the reactor were heated to at least 220° C. to prevent the condensation of ammonia iodide. During the deposition, the gaseous reagents are injected into the reactor at a distance of about 5 cm from the substrates. The flow of reagents was regulated by a MKS 1150 series vapor flow controller. The reactor temperature during all of the depositions was 600° C. The reagent flow, reactor pressure, and deposition rate are provided in Table I. The film refractive index, which was obtained by ellipsometry on a Rudolph Research Focus IV Ellipsometer measured at 632.8 nm is also provided in Table I.

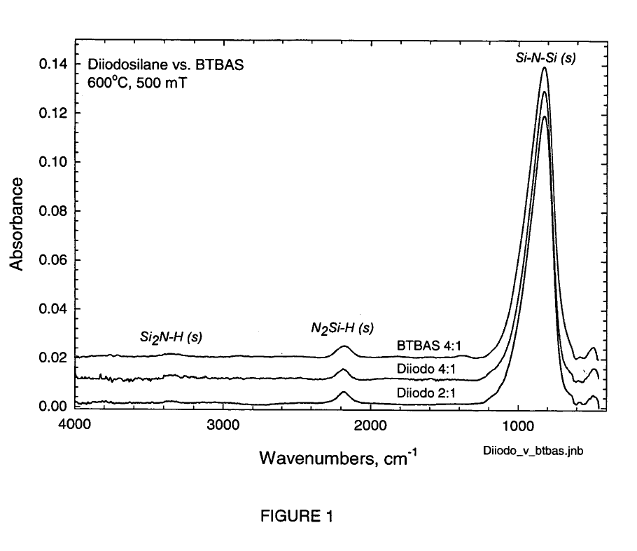

FIG. 1 provides that transmission FTIR spectra of exemplary silicon nitride films 1, 2, and a comparative silicon nitride film deposited using the precursor bis(tertiarybutylamino)silane (BTBAS) using a Bio-Rad FTS-7 at 4 cm⁻¹ resolution. As FIG. 1 shows, all of the films exhibited absorption bands in the Si—H region at 2200 cm⁻¹ and the Si—N region at 834 cm⁻¹. However, unlike the comparative film, exemplary films 1 and 2 which were deposited using the diodosilane precursor are free of the carbon incorporated in the comparative film as shown by the lack of absorption bands in the 1200 to 1400 cm⁻¹ range.

TABLE I

| | | | | | Film |
|---|---|---|---|---|---|
| | | | Reactor | Deposition | Refractive |
| | SiH₂I₂ flow | NH₃ flow | Pressure | Rate | Index (at |
| Example | (sccm) | (sccm) | (mTorr) | (nm/min) | 632.8 nm) |
| Ex. 1 | 30 | 120 | 500 | 0.57 | 1.958 |
| Ex. 2 | 60 | 120 | 500 | 1.3 | 2.00 |
| Ex 3 | 22 | 32 | 500 | 1.8-2.1 | 2.03 |

1. A process for forming a silicon-containing film, the process comprising:
introducing a substrate and gaseous reagents comprising an iodosilane precursor having three or less iodine atoms bound to the silicon atom and at least one reagent selected from an oxygen-containing reactive gas, a nitrogen-containing reactive gas, a hydrogen-containing reactive gas, a silicon-containing precursor, and mixtures thereof into a reaction chamber;
heating the reaction chamber to one or more temperatures ranging from 200° C. to 900° C. to form the silicon containing film on the substrate
provided that if the iodosilane precursor has three iodine atoms bound to the silicon atom then the heating step is conducted at one or more pressures less than 600 Torr.

2. The process of claim 1 wherein the iodosilane precursor is a compound of the formula I₍₄₋ₙ₎SiHₙ wherein n=1, 2, or 3.

3. The process of claim 1 wherein the at least one reagent comprises the nitrogen-containing reactive gas.

4. The process of claim 3 wherein the nitrogen-containing reactive gas is selected from ammonia, hydrazine, and mixtures thereof.

5. The process of claim 4 wherein the nitrogen-containing reactive gas is ammonia.

6. The process of claim 5 wherein the molar ratio of ammonia to the iodosilane precursor is at least 0.2:1.

7. The process of claim 3 wherein the at least one reagent comprises the oxygen-containing reactive gas.

8. The process of claim 7 wherein the oxygen-containing reactive gas is at least one selected from O₂, O₃, N₂O, NO₂, and mixtures thereof.

9. The process of claim 1 wherein the at least one reagent comprises the oxygen-containing reactive gas.

10. The process of claim 1 wherein the heating is conducted at one or more pressures ranging from 10 mTorr to 20 Torr.

11. A semiconductor substrate comprising the silicon containing film produced by the process of claim 1.

12. A process for the chemical vapor deposition of a silicon-containing film on a substrate comprising: contacting an iodosilane precursor having three or less iodine atoms bound to the silicon atom with at least one reagent selected from a nitrogen-containing reactive gas, an oxygen-containing reactive gas, a hydrogen-containing reactive gas, a silicon-containing precursor, and mixtures thereof at one or more temperatures ranging from 200° C. to 600° C. and one or more pressures less than 600 Torr to form the silicon-containing film on the substrate.

13. A process for low temperature chemical vapor deposition of a silicon-containing film on a substrate, the process comprising:
heating the substrate to a temperature ranging from 200° C. to 600° C. and a pressure ranging from 10 mTorr to 20 Torr in a reaction chamber;
introducing gaseous reagents comprising an iodosilane precursor having three or less iodine atoms bound to the silicon atom and an at least one reagent selected from an oxygen-containing reactive gas, a nitrogen-containing reactive gas, a hydrogen-containing reactive gas, a silicon-containing precursor, and mixtures thereof into the reaction chamber; and
maintaining the temperature and pressure for a period of time sufficient to deposit the silicon-containing film on the substrate.

14. A process for the deposition of a silicon-containing film on a substrate comprising reacting an iodosilane precursor having a formula I₍₄₋ₙ₎SiHₙ wherein n=1, 2, or 3 with at least one reagent selected from an oxygen-containing reactive gas, a nitrogen-containing reactive gas, a hydrogen-containing reactive gas, a silicon-containing precursor and mixtures thereof provided that if n=1 then the reacting step is conducted at a pressure ranging from 10 mTorr to 20 Torr.

15. A silicon-containing film formed by chemical vapor deposition of at least one chemical reagent comprising iodosilane having a formula I₍₄₋ₙ₎SiHₙ wherein n=1, 2, or 3 wherein the chemical vapor deposition is conducted at a temperature ranging from 200° C. to 600° C. and a pressure ranging from 10 mTorr to 20 Torr.

16. A reactive mixture for the deposition of a silicon-containing film comprising: an iodosilane having a formula I₍₄₋ₙ₎SiHₙ wherein n=1 or 2 and at least one reagent selected from an oxygen-containing reactive gas, a nitrogen-containing reactive gas, a hydrogen-containing reactive gas, a silicon-containing precursor and mixtures thereof.
